(19) United States
(12) Patent Application Publication
(10) Pub. No.: US 2010/0318235 A1
(43) Pub. Date: Dec. 16, 2010

(54) System for monitoring energy consumption of an electrical appliance

(76) Inventor: David Moss, Tucson, AZ (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 12/456,322

(22) Filed: Jun. 15, 2009

(51) Int. Cl. G06F 1/32; G06N 5/02; G06F 1/28; G01R 21/00; G06F 19/00

(52) U.S. Cl. 700/295; 706/47; 702/62; 702/188

(57) ABSTRACT

A system for monitoring energy consumption of an electrical appliance. The present invention provides an elegant means of monitoring energy consumption by legacy appliances such as a HVAC system. The energy consumption is monitored by the use of new and innovative wireless sensing device that is placed adjacent to or in contact with the appliance while it is operational. Appliance usage pattern information and power consumption information is communicated by the wireless sensing device and is collected by a gateway (and in some embodiments, an energy pump device, an intelligent power meter or a collector device). User behavior is modified by recommending approaches to cut energy consumption by the appliances thereby providing savings and reducing the cost of operation.

### CROSS REFERENCES TO RELATED APPLICATIONS

The present patent application is related to and makes reference to a co-pending application, entitled “A MONITORING SYSTEM FOR COLLECTION AND DISTRIBUTION OF A POWER CONSUMPTION INFORMATION”, filed on Mar. 31, 2009, docket number GWPP2009U1.

The present patent application is also related to and makes reference to a co-pending application, entitled “WEB BASED MONITORING, MANAGEMENT AND CONTEST BASED ON COLLECTED POWER CONSUMPTION DATA”, filed on Mar. 31, 2009, docket number GWPP2009U2.

The complete subject matter of the two above-referenced United States patent applications is hereby incorporated herein by reference, in their entirety. The present patent application and the above-referenced United States patent applications share the same inventors and have the same filing date.

### BACKGROUND

1. Technical Field

The present invention relates generally to energy saving and power consumption monitoring and particularly to a wireless sensing device that can be located adjacent to or in proximity to an appliance, such as a HVAC system, that monitors usage patterns and correlates that to power consumption.

2. Related Art

Power consuming appliances are becoming ubiquitous. People use electrical tools and appliances all over their residences. Some electrical appliances are turned on and seldom turned off, even when the user does not need the appliance or make use of it. Most people living in a modern house have a TV, a refrigerator, a washing machine, a washer, a dryer, a heating system, an air conditioner, etc. Most of these devices consume a lot of power when they are plugged into power outlets, some even when they are not being used.

Every day people use a lot of electricity for running appliances such as a refrigerator, but they don't know how much power these appliances consume. The doors of refrigerators are opened several times a day, and often for extended durations, thereby causing the refrigerator to use more power to keep things cool. Quite often the temperature settings on the refrigerator are inappropriate—set too high or set too low.

Unfortunately, despite widespread acceptance of green house effects and despite rise in the price of crude oil, people have not been provided with effective power saving technologies. People are being encouraged to turn off light bulbs when they are not in a room. Some appliance can be turned off if they are not being used. However, turning off a refrigerator when a user is travelling it is not an option as food stored in the refrigerator is likely to get spoiled when it is turned off. Thus, effective power saving mechanisms are lacking for appliances such as refrigerators.

Often people do not know how much power they can save by following all the typical power saving recommendations. Well meaning individuals have no idea how effective all their power saving efforts has been. Even if one were to use green electrical appliances, one does not know if one can be more effective in saving power by adopting better usage patterns.

There is a problem educating users on effective power management techniques that saves them money by reducing power consumption of their refrigerators and other appliances. Quite often, these individuals who have lowered their electric bills do not know how much individual appliances have contributed towards the savings in energy bills.

One of the big energy intensive appliances at home are the HVAC systems that are used to heat houses in winter and cool them in summer. It is important to be able to monitor the energy consumption of HVAC systems, especially the legacy HVAC systems that are difficult to monitor or relocate, and sometimes even expensive to replace. If the heater or air conditioning is plugged in, the plug is usually difficult to get to and may not be a standard type of connection. Sometimes the HVAC system may be hard wired and their plugs cannot be replaced or modified. This makes it difficult to explicitly measure how much energy the heater or air units of the HVAC system consume.

Another important high energy consumption item on a monthly energy bill is the various lamps and lights that are left on, sometimes throughout the day. The use of various lamp systems need to be properly managed and they must be turned off when not needed, but there are no easy ways in which people can be coaxed into turning them off when not needed. Most people forget to turn the lights off, and they do not know when these lamps have been left on inadvertently. Often, people forget that they had left their lights on when they go on a vacation and come back to realize that the lights were on for the entire duration of their vacation.

There are several types of appliances that consume a lot of energy and vibrate when active. Washers, dryers, refrigerator compressor, dishwashers, etc. all fall under this category of vibrating when active. It is generally not possible to automatically determine which of these appliances are being used on any given day, and how much these appliances contribute towards total energy consumption.

In view of the foregoing considerations, it is clear that there is a need for an improved system and method for measuring power consumption and monitoring power usage.

### BRIEF SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

BRIEF DESCRIPTION OF THE DRAWINGS

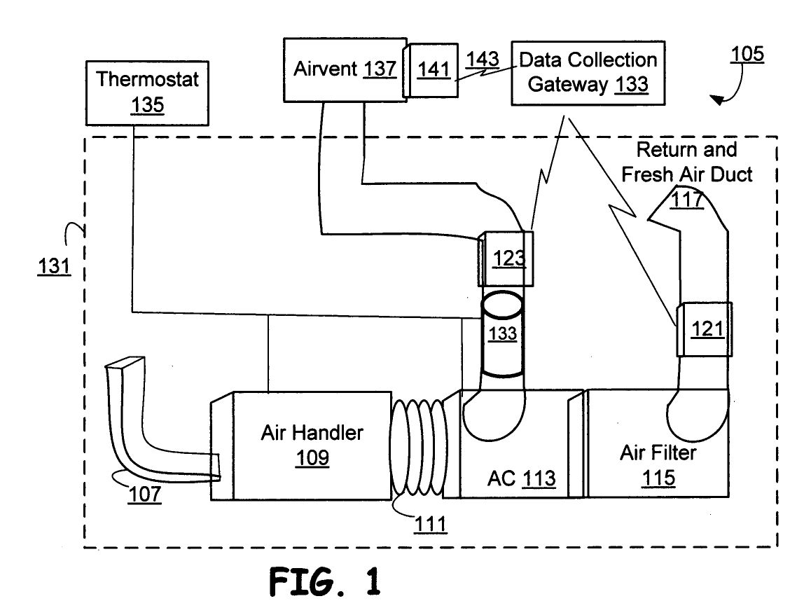

FIG. 1 is a perspective block diagram of a system for monitoring energy consumption of an electrical appliance.

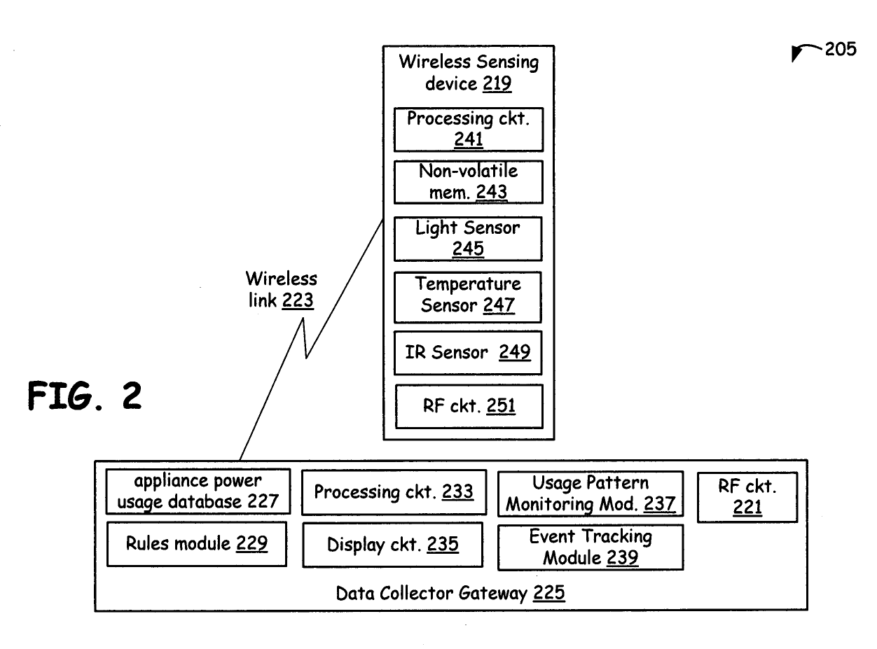

FIG. 2 is a perspective block diagram that shows the components of a wireless sensing device and a data collector gateway that interact with each other to form part of a system to monitor energy consumption of appliances.

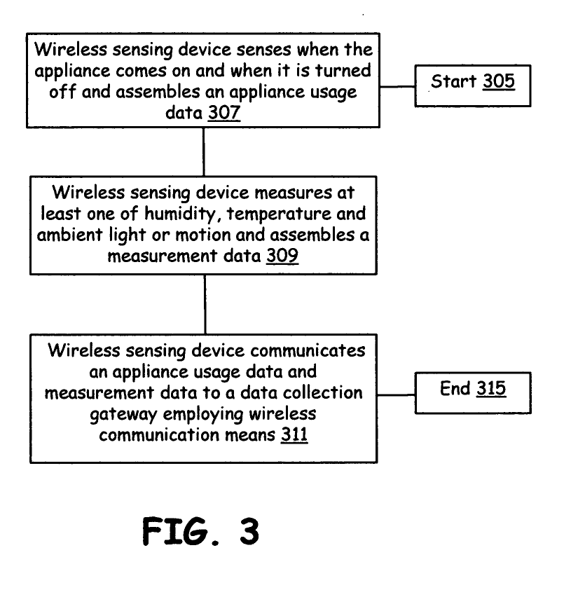

FIG. 3 is a flowchart of an exemplary operation of the system for monitoring energy consumption of an electrical appliance.

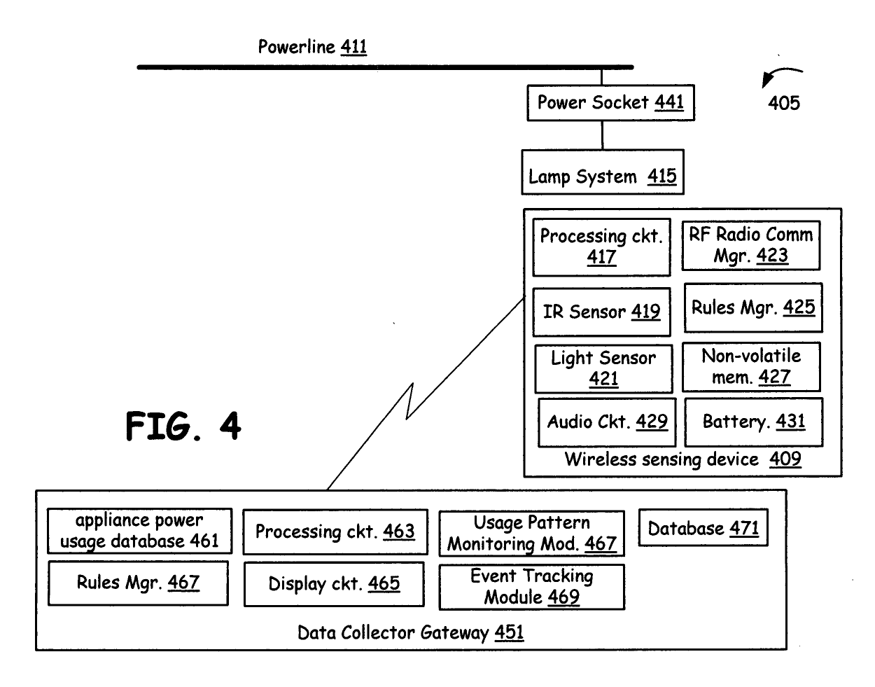

FIG. 4 is a perspective block diagram of a monitoring system for monitoring energy consumption of lamp system, wherein the system comprises one or more wireless sensing devices that are located in physical contact with or in sufficient proximity to the lamp system.

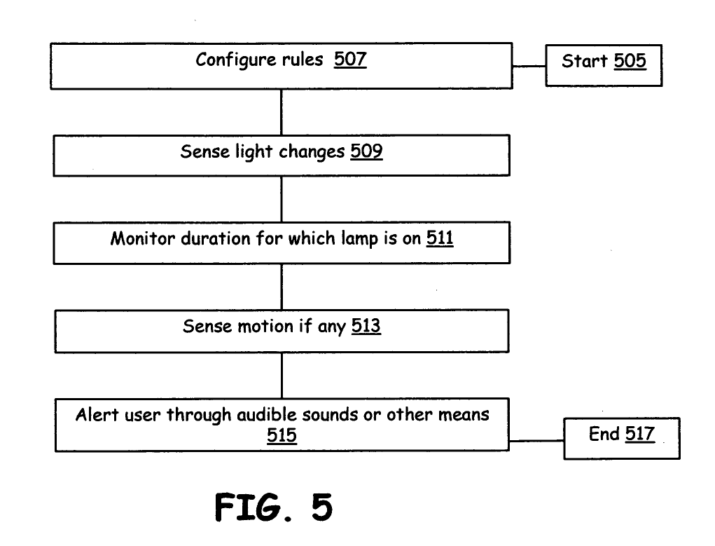

FIG. 5 is a flow chart of an exemplary operation of the monitoring system 405 for monitoring energy consumption of lamp system 415.

### DETAILED DESCRIPTION OF THE DRAWINGS

The present invention provides an elegant means of monitoring energy consumption by legacy appliances such as a HVAC system. The energy consumption is monitored by the use of new and innovative wireless sensing device that is placed adjacent to or in contact with the appliance while it is operational. Appliance usage pattern information and power consumption information is communicated by the wireless sensing device and is collected by a gateway (and in some embodiments, an energy pump device, an intelligent power meter or a collector device). User behavior is modified by recommending approaches to cut energy consumption by the appliances thereby providing savings and reducing the cost of operation.

FIG. 1 is a perspective block diagram of a system 105 for monitoring energy consumption of an electrical appliance 131. The system 105 comprises an appliance to which is attached one or more wireless sensing devices 121, 123, 141. One or more wireless sensing devices 121, 123, 141 are placed adjacent to, in proximity of, or attached to the appliance 131 to sense changes in light, temperature, etc. The wireless sensing devices 121, 123, 141 are communicatively coupled via the wireless link means to a collector data collection gateway 133. The wireless sensing devices 121, 123, 141 track user behavior as the user uses the appliance and they report such tracked data, changes in operation of the appliance, etc to the data collection gateway 133. For example, it keeps track of the number the times the appliance is used, the duration of its usage etc. It employs sensors to determine various measurements and the occurrence of events.

The system 105 for monitoring energy consumption of the electrical appliance 131 comprises one or more wireless sensing devices 121, 123, 141 that are located in physical contact with or in sufficient proximity to the appliance 131 being monitored (or in proximity to air vents 137 and other outlets in a building). It also comprises a data collection gateway 133 that collects data from the wireless sensing devices 121, 123 and manages its operation. The wireless sensing devices 121, 123, 141 sense when the appliance 131 comes on and when it is turned off and are capable of assembling an appliance 131 usage data. The wireless sensing device 131 measures at least one of humidity, temperature and ambient light and assembling a measurement data. The wireless sensing devices 121, 123 communicate an appliance usage data and measurement data to the data collection gateway 133 employing wireless communication means. In one embodiment, the wireless communication means is a WiFi based communication link. Other alternate communications means are also contemplated.

In one embodiment, the appliance 131 is a heating, ventilating, and air conditioning (HVAC) system in a building. The wireless sensing device 121 comprises a microphone to detect a constant flow of air, and is able to determine if hot air or cold air is blowing in the ducts of the HVAC 131. Specifically, the wireless sensing device 121 employs the microphone to determine if air is flowing through the ducts, thereby determining if the HVAC 131 is turned on. It employs a temperature sensor to detect the changes in temperature in the house/building. The wireless sensing device 121 also uses the microphone to determine if air has stopped flowing thereby determining if the HVAC 131 is turned off. The wireless sensing device 121 monitors the microphone to determine changes in the state of operation of the HVAC 131 and communicates it to the data collection gateway 133. The HVAC system 131 comprises ducts a supply duct 107, an air handler 109, a flexible connection 111, an air conditioning unit 113, a heater/heating coil 133, an air filter compartment 115, and a return and fresh air duct 117. In addition, an air vent 137 is connected to a duct of the HVAC system 131 to which the wireless sensing device 141 is attached (or placed in proximity).

In one embodiment, the system 105 monitors the operation of an appliance which is a lamp system comprising at least one bulb. In this case, the wireless sensing device 121 comprises at least one on-board light sensor to detect light and at least one passive infrared (PIR) sensor to detect motion in a room. It also comprises an audio circuitry to make a sound to draw attention and a battery power source to provide electric power to operate the wireless sensing device. It employs an RF radio for communication for communicating data collected and information on events detected to the data collection gateway 133 that monitors energy consumption by the appliance.

The system 105 supports specification of rules that influence monitoring of events and tracking of power consumption. For example, the rules are configured into the wireless sensing device 121 by a user via the data collection gateway 133. When used to monitor a lamp system, the wireless sensing device 121 accesses the rules configured to control the lamp system, wherein the rules are default rules or user customized rules. The wireless sensing device manages the state of the lamp system by turning the lamp system on or off automatically based on the rules.

The wireless sensing device 121 communicates employing an RF radio. It typically has on-board a few sensors for light, temperature and sound, such as a microphone to detect sound and a temperature digital thermometer sensor to detect changes in temperature. The wireless sensing device 121 is small, unobtrusive, and battery powered. The RF radio in the wireless sensing device 121 allows it to communicate with an existing wireless infrastructure in the building and is able to participate in monitoring appliance energy consumption.

In one embodiment, when used with the HVAC system 131, the wireless sensing device 141 is attached to an air vent 137 in a room in the house, or to a return and fresh air duct 117. It can be placed behind an air vent 137 so that a person in the room does not see it, or it can simply be attached to the front of an air vent 137 in a room. Thus, the wireless sensing device 141 determines when the heater coil 133 or air conditioner (AC) 113 is turned on. It uses the microphone to hear a constant flow of air, which is often audible and makes a sound similar to white noise or static on the microphone. The wireless sensing device 141 uses its temperature sensor to eventually determine whether the temperature is getting hotter or colder, and it determines whether the heater 133 is being used or the air conditioning unit 113. When the heater 133 or AC 113 turns on and hot or cold air blows across the wireless sensing device 141, it wirelessly alerts the data collection gateway (one specific product in the market is the GreenPump from PeoplePower) through the ad-hoc wireless communication means 143. Such communication may take several messages—one to alert the data collection gateway 133 that the air has started flowing through the air vent 137, and another message to confirm whether it's the heater 133 or the air conditioning unit 113 that was enabled. In a related embodiment, the data collection gateway 133 retrieves sensor data collected by an external device that tracks and monitors a total home's energy consumption (such as a GreenSentry device) and computes an approximate energy consumption estimate for the HVAC system. For example, by retrieving information on the amount of energy consumed before the HVAC is turned on, and the rate of energy consumption after the HVAC is turned on, it determines how much energy the AC unit 113 or the heater 133 consumes, over time. Thus the wireless sensing device makes it possible to determine energy consumption in the building while the heater 133 is being used, or while the AC unit 113 is being used, without requiring the user to tap into the legacy electrical lines powering the HVAC system, etc.

In one embodiment, the wireless sensing device, such as the wireless sensing device 121, comprises a sensor to detect vibrations of appliances that indicate that the appliances are being used. Appliances such as washers, dryers, dishwashers, etc. come under a category of appliances whose operations can be detected using vibration sensors. The wireless sensing device that can detect vibrations is mechanically coupled to these appliances—i.e. with a magnet to attach to the appliance. Alternately, the wireless sensing device is located (placing the wireless sensing device) inside or on top of the appliance. It would then sense vibration, such as by employing a tilt sensor or an accelerometer, and would therefore be able to determine if the appliance is currently active or not. The data collector gateway correlates energy consumption to the individual appliance and determines which part of the total home energy consumption is attributable to the active appliance. Thus energy consumed by the active appliance is determined and tracked over time.

To detect vibrations from appliances, wherein such vibrations indicate the operational state of an appliance, the wireless sensing device employs appropriate vibration sensors. For example, the wireless sensing device, in one embodiment, employs a tilt sensor that can detect movements in one or 2 axis, that provide a binary output. Thus, for some embodiments, a simple 1- or 2-axis sensor with a binary output would suffice to detect vibrations. Specifically, in a 1-axis version, a metal ball rolls up and down inside a small ‘pipe’ and makes or breaks electrical contact. It can measure a change if the angle of the tilt is along the axis of the pipe, so the ball inside can roll from one side to the other.

In one embodiment, the wireless sensing device employs a 2-axis tilt sensor. For example, it employs one where a metal ball moves in 2-dimensions in an enclosed circular arena. The metal ball in the sensor moves inside its enclosure whenever the wireless sensing device tilts along the X- or Y-axis and makes or breaks contact with electrical pads, which is detected and tracked.

In a related embodiment, the wireless sensing device employs an accelerometer to detect movement of an appliance as it is used actively. In the case of a washing machine or a dryer, for example, such a wireless sensing device would comprise a 3-axis accelerometer. The wireless sensing device would be able to detect the pull of gravity as well as the amount of vibration in any direction. The output of such an accelerometer is typically analog, and digital ADC readings are read over a standard microcontroller communication bus.

FIG. 2 is a perspective block diagram that shows the components of a wireless sensing device 219 and a data collector gateway 225 that interact with each other to form part of a system to monitor energy consumption of appliances. The wireless sensing device 219 and a data collector gateway 225 employ a wireless link 223 to communicate, such as wireless links that employ an 802.11 based protocol or a similar protocol. The wireless sensing device 219 represents common features of wireless sensing devices 121, 123, 141 of FIG. 1.

The wireless sensing device 219 comprises a processing circuitry 241 and a non-volatile memory 243 that is used to store rules, configurations, collected data, measurements, etc. It also comprises a light sensor 245 to detect changes in ambient light, a temperature sensor 247 to detect changes in temperature, an infra red (IR) sensor 249 to detect motion and an radio frequency (RF) circuitry to communicate employing wireless communication protocols.

The data collector gateway 225 comprises a processing circuitry 233, a display circuitry 235, an appliance power usage database 227 that is used to store collected data, and a rules module 229 that is used to manage wireless sensing devices 219 that also manages rules to be transferred to the wireless sensing devices 219. It also comprises a an RF circuitry 221 that supports communication with the wireless sensing device 219, an usage pattern monitoring module 237 that determines appliance usage patterns over time, and an event tracking module 239 that keeps track of when and for how long the various appliances are started, kept in various operational states and turned off.

The data collector gateway 225 communicates user generated rules or default rules to the wireless sensing devices 219. The wireless sensing devices 219 operates its data collection and measurement operations based on these rules.

FIG. 3 is a flowchart of an exemplary operation of the system 105 for monitoring energy consumption of an electrical appliance 131. The operation starts at a start block 305 when the wireless sensing device 121 (or 133, 141) is placed in proximity to an appliance or attached to an appliance. Then, at a next block 307, the wireless sensing device senses the operations of the appliance. For example, it senses when the appliance comes on and when it is turned off and it also assembles an appliance usage data. It detects various events as the appliance changes its operational modes.

Then, at a next block 309, the wireless sensing device measures at least one of humidity, temperature, ambient light and motion. It assembles a measurement data that can be communicated to the data collector gateway. The wireless sensing device employs a light sensor to detect changes in ambient light, an IR sensor to detect motion, a temperature sensor to detect changes in temperature, and a humidity sensor to detect changes in humidity.

Then, at a next block 311, the wireless sensing device communicates the appliance usage data, the measurement data and other related information to the data collector gateway employing wireless communication means such as IR, WiFi, cellular communications, etc. Then, the operation terminates at an end block 315.

FIG. 4 is a perspective block diagram of a monitoring system 405 for monitoring energy consumption of lamp system 415, wherein the system comprises one or more wireless sensing devices 409 that are located in physical contact with or in sufficient proximity to the lamp system 415. The wireless sensing device 409 comprises a processing circuitry 417, an RF radio communication manager circuitry 423, an IR sensor 419, a rules manager 425, a light sensor 421, a non-volatile memory 427, an audio circuitry 429 and a battery 431.

The lamp system 415 comprises at least one bulb that lights up when the lamp system is turned on. The light sensor 421 of the wireless sensing device 409 tracks changes in ambient light to determine whether the lamp system 415 is turned on. The wireless sensing device tracks the duration for which the lamp system 415 is turned on. The wireless sensing device 409 reports lamp system 415 usage information to the data collector gateway 451.

The IR sensor 419 in the wireless sensing device 409 is capable of detecting motion in the premises. If it does not determine any motion for a configured duration, the wireless sensing device 415, based on rules configured, communicates an alert message to the data collector gateway 451 to highlight the need to turn the lamp system off to reduce energy consumption.

In one embodiment, the wireless sensing device 409 has an on-board passive infrared (PIR) component for the IR sensor 419, and a photodiode for the light sensor 421. It also comprises a buzzer/speaker for the audio circuitry 429. The wireless sensing device 409 is small, unobtrusive, and battery powered. The RF radio communication manager 423 allows it to communicate with an existing wireless infrastructure in the building if necessary, or with the data collector gateway 451 that monitors appliance energy consumption.

The wireless sensing device 409 detects when the lights are turned on in a room by activating the lamp system 415. The light sensor 421 is able to detect when the room is sufficiently lit up. It then communicates that information (based on rules for example) to the data collector gateway 451 or to other wireless sensing device if necessary. The data collector gateway 451 keeps track of time to determine if it is dark outside the house (night time) and if the lights detected in the room are most likely from light bulbs from the lamp system 415 and not the sun. The wireless sensing device 409 detects motion and it determines if people are in the room when the lights are on. The passive infrared sensor 419 can detect motion and if the lights are on when motion is detected, then there is no need to take any action. If it detects that the lights are on and there is no motion detected for a configured duration, the wireless sensing device 409 alerts a user that the lights are left on in the room and they may have to turn it off. The wireless sensing device 409 plays an audio data or beeps to attract attention, if necessary, when it determines that energy is being wasted by keeping the lights on when not necessary. An alert to the user can also be sent using SMS or email.

In one embodiment, controllable power sockets are used into which the appliance (lamp system or HVAC) is plugged in, and based on rules managed by the data collector gateway 451, the lamp system can be turned on or off and the HVAC system can be managed (heater turned on, AC turned off, etc.). Rules can be specified, such as “If there is motion detected by the wireless sensing device in a room, turn on the controllable power sockets and let the lamp system turn on (and light the room)”, or “if there is no motion in the room for 10 minutes, turn off the power to the lamp system”.

FIG. 5 is a flow chart of an exemplary operation of the monitoring system 405 for monitoring energy consumption of lamp system 415. At a start block 505, the wireless sensing device 409 interacts with and is recognized by the data collector gateway 451. Then, at a next block 507, the user configures rules for the operation of the wireless sensing device 409, via the data collector gateway 451, as it is placed in the proximity of the lamp system 415. At the next block 509, the wireless sensing device 409 senses the ambient light changes in the room. It determines if the lamp system 415 has been turned on or off. Later, at a next block 511, it monitors the duration for which the lamp system 415 is on.

At a next block 513, the wireless sensing device 409 detects motion, if any, in the room where the lamp system 415 is located. If it senses motion, it determines that the room is being used and the lamp system can continue to stay on. If it determines if the lamp system 415 is off and there is no motion detected in the room for a significant amount of time (based upon a threshold duration), it determines the need to alert a user.

Then, at a next block 515, when the wireless sensing device 409 determines the need to alert a user, the wireless sensing device 409 alerts the user through audible sounds or through other means such as email or an SMS message. Audible sounds can be a buzzing sound or a beeping sound to attract attention, or a tune played on a speaker.

Finally, the operation terminates at an end block 517.

As one of ordinary skill in the art will appreciate, the terms “operably coupled” and “communicatively coupled,” as may be used herein, include direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled” and “communicatively coupled.”

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

What is claimed is:

1. A method of monitoring energy consumption of a home appliance, the method comprising:
sensing, employing a wireless sensing device that is in sufficient proximity to the appliance being monitored, when the appliance comes on and when it is turned off and assembling an appliance usage data;
measuring, employing the wireless sensing device, at least one of humidity, temperature, vibration and ambient light and assembling a measurement data; and
communicating an appliance usage data and measurement data to a data collection gateway by the wireless sensing device employing wireless communication means.

2. The method of monitoring of claim 1 wherein the appliance is an heating, ventilating, and air conditioning (HVAC) system in a building.

3. The method of claim 3 wherein the wireless sensing device comprises a microphone to hear a constant flow of air, the sensing operation comprising:
employing the microphone to determine if air is flowing thereby determining if the HVAC is turned on;
using the microphone to determine if air has stopped flowing thereby determining if the HVAC is turned off; and
monitoring the microphone to determine changes in the state of operation of the HVAC.

4. The method of claim 3 wherein the wireless sensing device also comprises a temperature sensor, the sensing operation further comprising:
tracking the temperature sensor to determine whether the temperature is getting hotter or colder, so as to determine if a heater unit is being used to blow heated air or if an air conditioning unit is being used to blow cold air.

5. The method of claim 1 wherein communicating comprises:
alerting the data collection gateway, by the wireless sensing device, that the appliance has changed state in its operation;
sending, by the wireless sensing device to the data collection gateway the appliance usage data and measurement data employing wireless communication means; and
receiving, by the data collection gateway, the appliance usage data and the measurement data, from the wireless sensing device.

6. The method of claim 5 wherein the appliance is a HVAC system in a building, the method the further comprising:
identifying by the wireless sensing device whether it's the heater unit or the air conditioning unit that is enabled.

7. The method of claim 6 wherein the appliance is a HVAC system in a building, the method the further comprising:
pulling sensor data from an sentry device located outside the building that provides an overall energy consumption data;
computing an approximate energy consumption data for the HVAC system; and
keeping track of the amount of time for which the heater unit or the air conditioning unit is kept open and f energy consumed for that duration.

8. The method of claim 1 wherein the wireless sensing device comprises:
at least one on-board light sensor to detect light;
at least one passive infrared (PIR) sensor to detect motion in a room;
an audio circuitry to make a sound to draw attention;
a battery power source to provide electric power to operate the wireless sensing device; and
a RF radio for communication for communicating data collected and information on events detected to the data collection gateway that monitors energy consumption by the appliance.

9. The method of claim 8 wherein the appliance is a lamp system with at least one bulb, the method further comprising:
accessing rules to control the lamp system, wherein the rules are default rules or user customized rules; and
managing the state of the lamp system by turning the lamp system on or off automatically based on the rules.

10. A system for monitoring energy consumption of an appliance, the system comprising:
a wireless sensing device that is located in physical contact with or in sufficient proximity to the appliance being monitored;
a data collection gateway that collects data from the wireless sensing device and manages its operation;
the wireless sensing device sensing when the appliance comes on and when it is turned off and assembling an appliance usage data;
the wireless sensing device measuring at least one of humidity, temperature and ambient light and assembling a measurement data; and
the wireless sensing device communicating an appliance usage data and measurement data to the data collection gateway employing wireless communication means.

11. The system of claim 10 wherein the appliance is an heating, ventilating, and air conditioning (HVAC) system in a building.

12. The system of claim 11 wherein the wireless sensing device comprises a microphone to detect a constant flow of air, the system further comprising:
the wireless sensing device employing the microphone to determine if air is flowing, thereby determining if the HVAC is turned on;
the wireless sensing device using the microphone to determine if air has stopped flowing thereby determining if the HVAC is turned off; and
the wireless sensing device monitoring the microphone to determine changes in the state of operation of the HVAC and communicating it to the data collection gateway.

13. The system of claim 10 wherein the appliance is a lamp system comprising at least one bulb, the wireless sensing device comprising:
at least one on-board light sensor to detect light;
at least one passive infrared (PIR) sensor to detect motion in a room;
an audio circuitry to make a sound to draw attention;
a battery power source to provide electric power to operate the wireless sensing device; and
an RF radio for communication for communicating data collected and information on events detected to the data collection gateway that monitors energy consumption by the appliance.

14. The system of claim 13 further comprising:
rules configured in the wireless sensing device by a user via the data collection gateway;
the wireless sensing device accessing the rules configured to control the lamp system, wherein the rules are default rules or user customized rules; and
the wireless sensing device managing the state of the lamp system by turning the lamp system on or off automatically based on the rules.

15. A system for sensing operational states of an appliance, the system comprising:
a wireless sensing device comprising:
a light sensor to sense light changes;
a temperature sensor to sense temperature changes; and
an infra red (IR) sensor to sense motion;
a vibration sensor to detect vibrations and movement;
a gateway communicatively coupled to the wireless sensing device;
rules configured in the wireless sensing device; and
the wireless sensing device monitoring changes in light, temperature or motion and reporting it to the gateway based on the rules.

16. The system of claim 15 wherein the appliance is a HVAC system and wherein the wireless sensing device is attached to the HVAC system such that is capable of detecting the changes in an operational state of the HVAC system.

17. The system of claim 16 further comprising.
the wireless sensing device alerting the gateway that the appliance has changed state in its operation;
the wireless sensing device sending the data collection gateway an appliance usage data and a measurement data employing wireless communication means; and
the data collection gateway receiving the appliance usage data and the measurement data from the wireless sensing device.

18. The system of claim 16 further comprising.
the wireless sensing device tracking the temperature sensor to determine whether the temperature is getting hotter or colder, so as to determine if a heater unit in the HVAC system is being used to blow heated air or if an air conditioning unit in the HVAC system is being used to blow cold air;

19. The system of claim 15 wherein the appliance is a lamp system with at least one bulb, the system further comprising.
the light sensor of the wireless sensing device tracking changes in ambient light to determine whether the lamp system is turned on;
the wireless sensing device tracking the duration for which the lamp system is turned on; and
the wireless sensing device reporting lamp system usage information to the gateway.

20. The system of claim 19 further comprising:
the IR sensor in the wireless sensing device not determining any motion for a configured duration and the wireless sensing device, based on rules configured, communicating an alert message to the gateway to highlight the need to turn the lamp system off to reduce energy consumption.
